(19) United States
(12) Patent Application Publication
(10) Pub. No.: US 2026/0236654 A1
(43) Pub. Date: Aug. 13, 2026

(54) METHOD OF DESIGNING SEMICONDUCTOR DEVICE AND SYSTEM PERFORMING THE SAME

(71) Applicant: TAIWAN SEMICONDUCTOR MANUFACTURING COMPANY, LTD., Hsinchu (TW)

(72) Inventors: Zong-Ying HO, Hsinchu County (TW); Ming-Wen LIN, Hsinchu County (TW); Hsien YU TSENG, Miaoli County (TW); Wei-Ming CHEN, KeeLung City (TW); Ming-Chieh LI, Hsinchu County (TW)

(73) Assignee: TAIWAN SEMICONDUCTOR MANUFACTURING COMPANY, LTD., Hsinchu (TW)

(21) Appl. No.: 19/052,049

(22) Filed: Feb. 12, 2025

(51) Int. Cl. G06F 30/3308

(52) U.S. Cl. CPC G06F 30/3308

(57) ABSTRACT

A method includes following operations. A parameter table is generated based on schematic data. A first parameter group in the parameter table is sorted. Combinations of the first parameter group are checked. At least one invalid combination from the combinations is removed to generate a valid combination table. Simulations are executed to valid combinations in the valid combination table.

### BACKGROUND

In the mature process of semiconductor devices, all parameters are continuous and independent. However, in the advanced process, some dimension is forbidden due to fabrication. Some incorrect combinations of parameters will be triggered. Running the incorrect combinations lead to wasted simulation runtime.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a method illustrated in accordance with some embodiments of the present disclosure.

FIG. 2A is a circuit diagram of a semiconductor device illustrated in accordance with some embodiments of the present disclosure.

FIG. 2B is a schematic diagram of the operation shown in FIG. 1, for selecting instances from a circuit design, illustrated in accordance with some embodiments of the present disclosure.

FIG. 3A is a schematic diagram of the operation shown in FIG. 1, for generating the parameter table, illustrated in accordance with some embodiments of the present disclosure.

FIG. 3B is a schematic diagram of the operation shown in FIG. 1, regarding details of generating the parameter table, illustrated in accordance with some embodiments of the present disclosure.

FIG. 3C is a schematic diagram of the operation shown in FIG. 1, for generating an user modified parameter table, illustrated in accordance with some embodiments of the present disclosure.

FIG. 3D is a schematic diagram of the operation shown in FIG. 1, for sorting a sequence of the parameters according to the parameter order, illustrated in accordance with some embodiments of the present disclosure.

FIG. 3E is a schematic diagram of the operation shown in FIG. 1, for removing the invalid combinations according to predetermined rules, illustrated in accordance with some embodiments of the present disclosure.

FIG. 4 is a flowchart diagram of a method for performing the operation shown in FIG. 3E, illustrated in accordance with some embodiments of the present disclosure.

FIG. 5A is a flowchart diagram of another method for performing the operation shown in FIG. 3E, illustrated in accordance with some embodiments of the present disclosure.

FIG. 5B is a schematic diagram of for performing the method shown in FIG. 5A, illustrated in accordance with some embodiments of the present disclosure.

FIG. 6 is a flowchart diagram of a method for generating a parameter priority list, illustrated in accordance with some embodiments of the present disclosure.

FIG. 7 is a schematic view of a system for performing at least one of the method and operations described above, illustrated in accordance with some embodiments of the present disclosure.

FIG. 8 is a block diagram of an integrated circuit (IC)/semiconductor device manufacturing system, and an IC manufacturing flow associated therewith, illustrated in accordance with some embodiments of the present disclosure.

FIG. 9A is a flowchart diagram of a method for designing the semiconductor device of the circuit design, illustrated in accordance with some embodiments of the present disclosure.

FIG. 9B is a flowchart diagram of a method for designing the semiconductor device of the circuit design, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

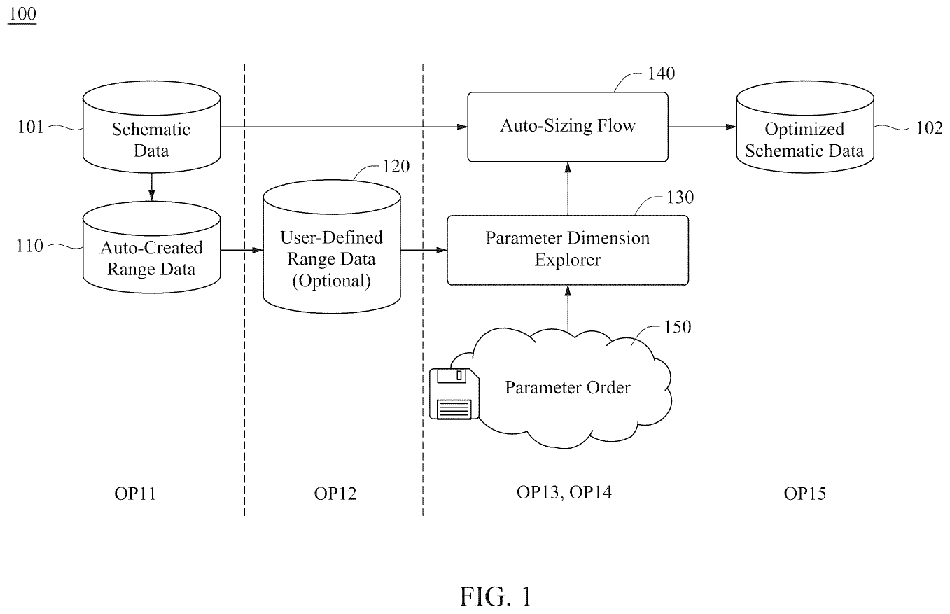

FIG. 1 is a schematic diagram of a method 100 illustrated in accordance with some embodiments of the present disclosure. In some embodiments, the method 100 is performed to determine optimized schematic data 102 of a semiconductor device, such that the semiconductor device is manufactured according to the optimized schematic data 102. As illustratively shown in FIG. 1, the method 100 includes operations OP11-OP15. In some embodiments, the operations OP11-OP15 are performed in order.

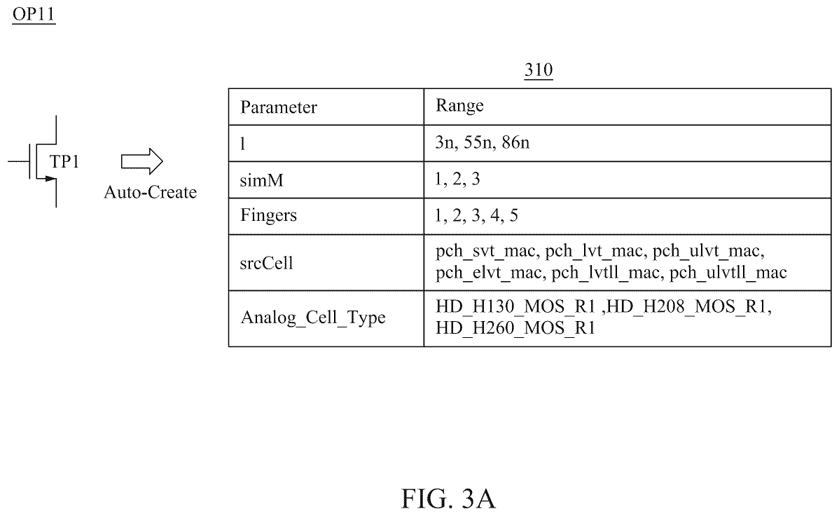

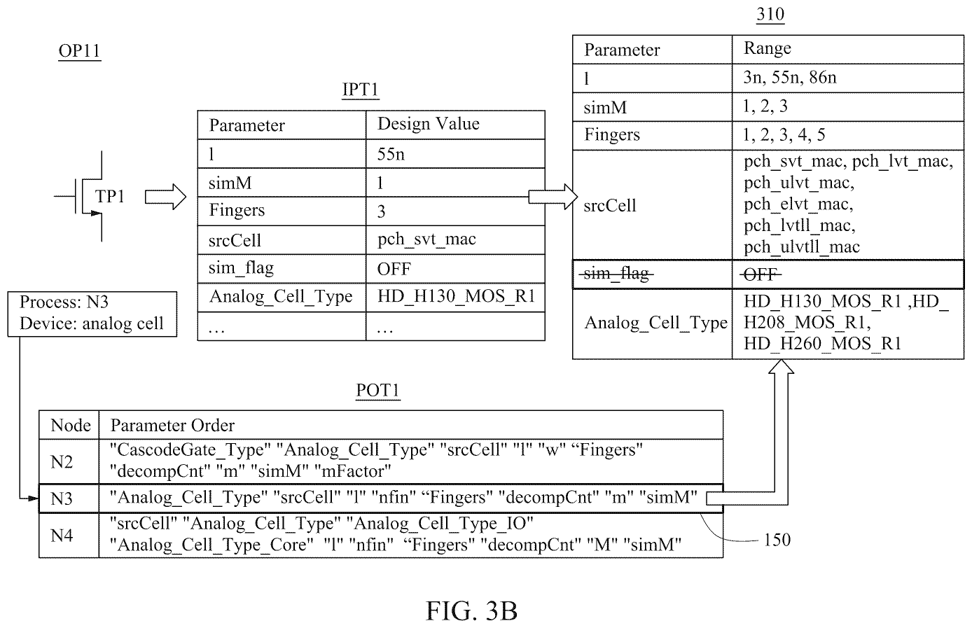

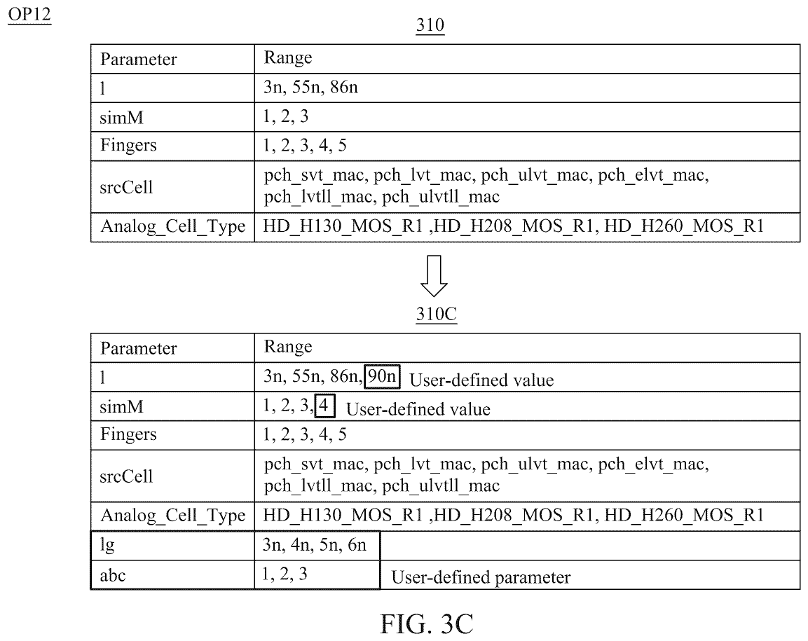

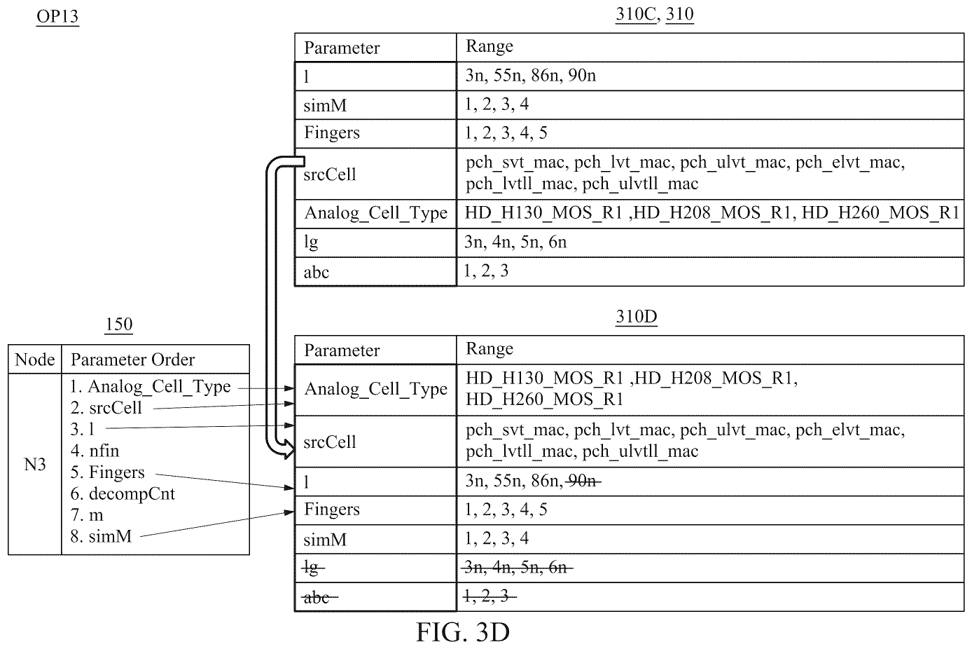

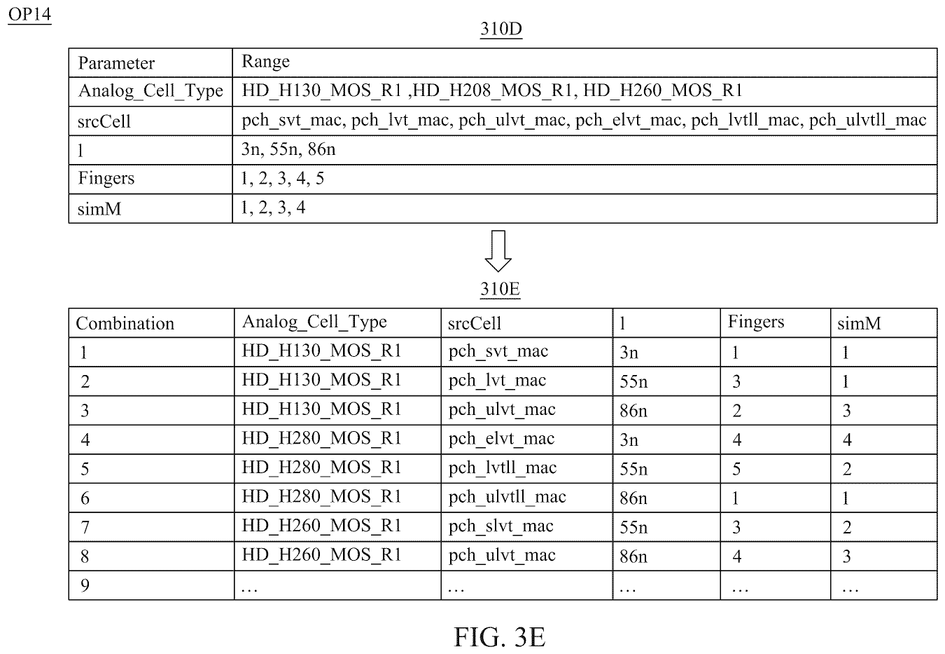

During the operation OP11, a parameter table, such as a parameter table 310 shown in FIG. 3A, is generated based on schematic data 101 and range data 110. In some embodiments, the schematic data 101 includes element parameters of a circuit design of the semiconductor device, and the range data 110 includes ranges of the element parameters. In some embodiments, the range data 110 is auto-created according to the schematic data 101 and current process design kit (PDK) by a processor. Further details regarding the operation OP11 are described below with the embodiments associated with FIG. 3A and FIG. 3B.

During the operation OP12, the parameter table 310 is modified based on user-defined range data 120. It is noted that the operation OP12 is optional. Alternatively stated, the operation OP12 is not performed in some embodiments. In such embodiments, the parameter table 310 is not modified based on the user-defined range data 120, and the operation OP13 is performed directly to the parameter table 310 after the operation OP11. Further details regarding the operation OP12 are described below with the embodiments associated with FIG. 3C.

During the operation OP13, a parameter dimension explorer 130 sorts a sequence of the parameter table 310, and removes invalid parameter values in the parameter table 310 according to a parameter order 150, to generate a sorted parameter table, such as a sorted parameter table 310D shown in FIG. 3D. Further details regarding the operation OP13 are described below with the embodiments associated with FIG. 3D.

During the operation OP14, the parameter dimension explorer 130 performs auto-sizing flow to check combinations corresponding to the sorted parameter table 310D and remove invalid combinations, to generate a valid combination table, such as a valid combination table 310E shown in FIG. 3E. Further details regarding the operation OP14 are described below with the embodiments associated with FIG. 3E.

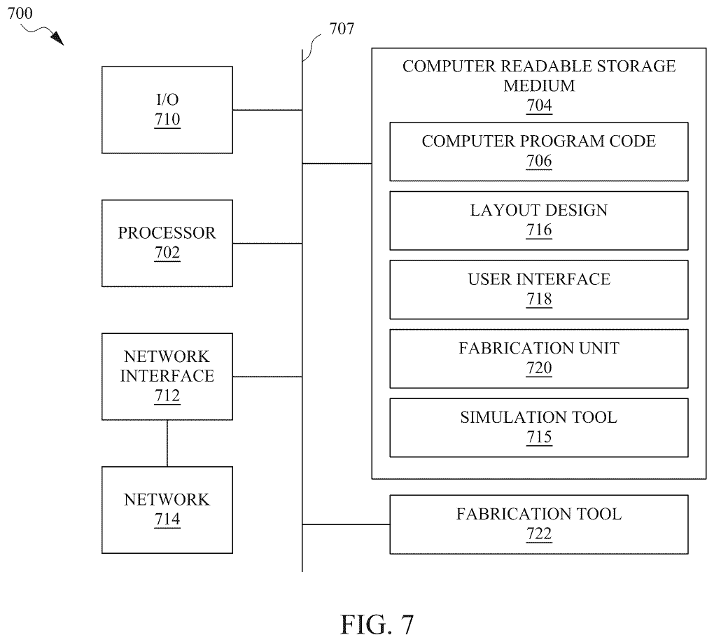

During the operation OP15, after the invalid combinations are removed, a simulation tool, such as a simulation tool 715 shown in FIG. 7, sets valid combinations as input of the simulation tool and runs parameter optimization. Specifically, the simulation tool runs simulations of the valid combinations to generate performances of the valid combinations. The processor compares performances of the valid combinations, and selects one of the valid combinations with the best performance for the optimized schematic data 102. Alternatively stated, the optimized schematic data 102 has a parameter combination with the best performance among the combinations in the valid combination table 310E.

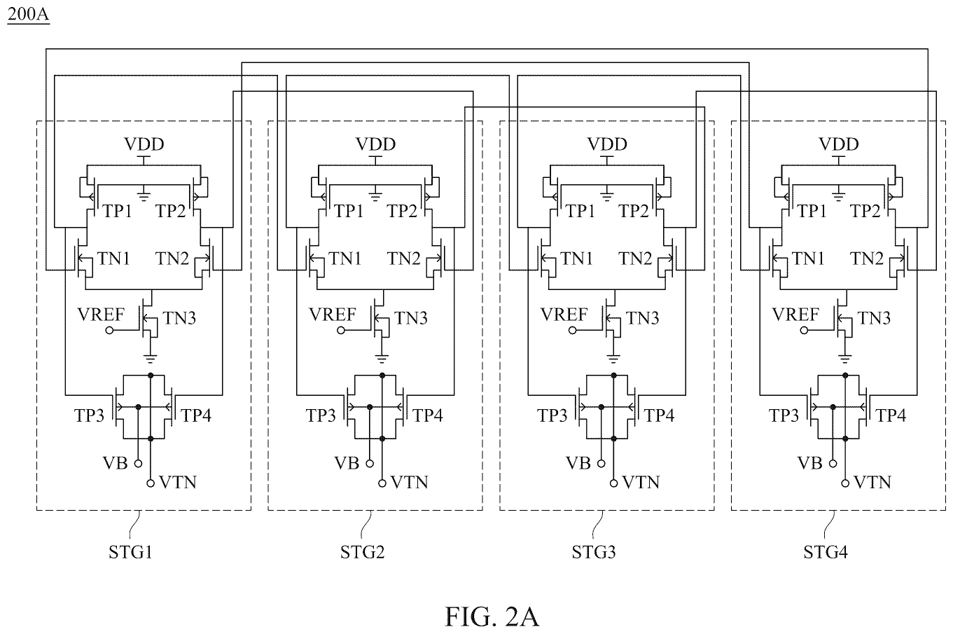

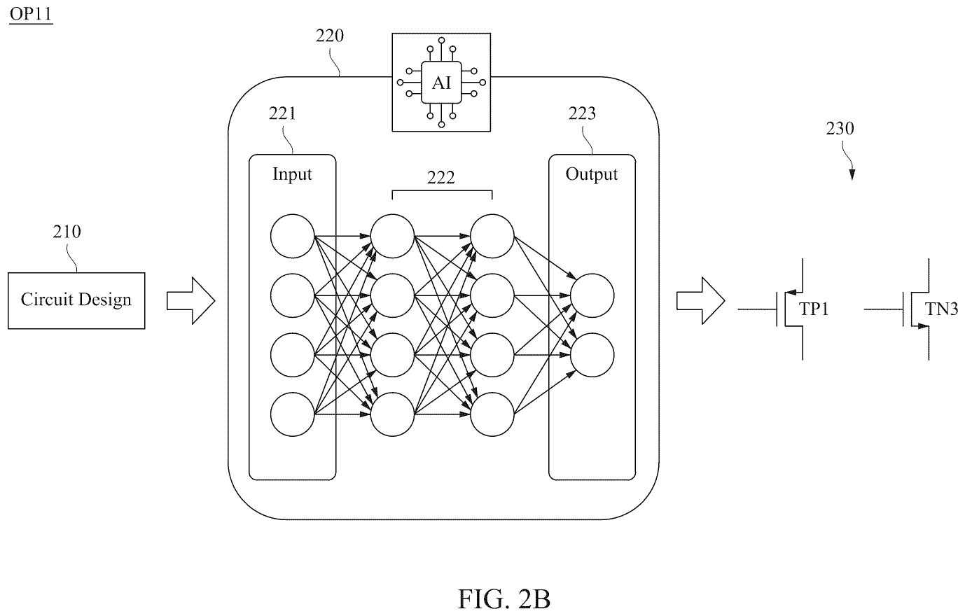

FIG. 2A is a circuit diagram of a semiconductor device 200A illustrated in accordance with some embodiments of the present disclosure. In the embodiment shown in FIG. 2A, the semiconductor device 200A is implemented by a four stages ring voltage controlled oscillator (VCO). However, the embodiments of the present disclosure are not limited to this. In various embodiments, the semiconductor device 200A is implemented by various devices.

As illustratively shown in FIG. 2A, the semiconductor device 200A includes stages STG1-STG4. Each of the stages STG1-STG4 includes switches TP1-TP4 and TN1-TN3. Each of control terminals of switches TP1 and TP2 is coupled to a ground terminal. A terminal of the switch TP1 is configured to receive a power voltage signal VDD, and another terminal of the switch TP1 is coupled to a terminal of the switch TN1. A terminal of the switch TN3 is coupled to each of the switches TN1 and TN2. Another terminal of the switch TN3 is coupled to the ground terminal. A control terminal of the switch TN3 is configured to receive a reference voltage signal VREF. The switch TN1 is coupled between the switches TP1 and TN3. The switch TN2 is coupled between the switches TP2 and TN3. Each of two terminals of the switch TP3 is configured to receive a tune voltage signal VTN. A control terminal of the switch TP3 is coupled to each of the switches TP1 and TN1. A body terminal of the switch TP3 is configured to receive a bias voltage signal VB. Each of two terminals of the switch TP4 is configured to receive the tune voltage signal VTN. A control terminal of the switch TP4 is coupled to each of the switches TP2 and TN2. A body terminal of the switch TP4 is configured to receive the bias voltage signal VB.

Furthermore, the stages STG1-STG4 are coupled to each other. Specifically, a control terminal of the switch TN1 in the stage STG1 is coupled to the control terminal of the switch TP4 in the stage STG4. The control terminal of the switch TP3 in the stage STG1 is coupled to a control terminal of the switch TN1 in the stage STG2. A control terminal of the switch TN2 in the stage STG1 is coupled to the control terminal of the switch TP3 in the stage STG4. The control terminal of the switch TP4 in the stage STG1 is coupled to a control terminal of the switch TN2 in the stage STG2.

Similarly, a control terminal of the switch TN1 in the stage STG3 is coupled to the control terminal of the switch TP3 in the stage STG2. The control terminal of the switch TP3 in the stage STG3 is coupled to a control terminal of the switch TN1 in the stage STG4. A control terminal of the switch TN2 in the stage STG3 is coupled to the control terminal of the switch TP4 in the stage STG2. The control terminal of the switch TP4 in the stage STG3 is coupled to a control terminal of the switch TN2 in the stage STG4.

In some embodiments, the switches TN1-TN3 are implemented by transistors of a first conductive type, such as N-type metal-oxide-semiconductor (NMOS) transistors. The switches TP1-TP4 are implemented by transistors of a second conductive type different from the first conductive type, such as P-type metal-oxide-semiconductor (PMOS) transistors.

FIG. 2B is a schematic diagram of the operation OP11 shown in FIG. 1, for selecting instances 230 from a circuit design 210, illustrated in accordance with some embodiments of the present disclosure. In some embodiments, artificial intelligence (AI), such as a machine learning model 220, is used to select the instances 230.

As illustratively shown in FIG. 2B, during the operation OP11, the instances of the circuit design 210 and the connections of the instances are inputted into the machine learning model 220 as input data 221. Then, the machine learning model 220 processes the instances of the circuit design 210 by a neutral network 222. The neutral network 222 selects the instances 230 from the instances of the circuit design 210, and outputs the instances 230 as the output data 223.

In some embodiments, the instances 230 are referred to as the sensitive instances of the circuit design 210. Alternatively stated, the instances 230 have a relatively large impact on the performance of the circuit design 210, compared to other instances of the circuit design 210. Specifically, when the parameters of the instances 230 are changed, the performance of the circuit design 210 has a larger variation, compared to a condition that the parameters of the other instances are changed.

During a training stage of the machine learning model 220, instances of multiple circuit designs are inputted into the machine learning model 220 as input training data. The machine learning model 220 generates the output data 223, and compares the output data 223 with sensitive instances of the input training data. When the output data 223 is different from the sensitive instances, weight parameters of the neutral network 222 is adjusted. After the weight parameters are adjusted, the adjusted machine learning model 220 generates the output data 223 again, and compares the output data 223 with the sensitive instances again. The neutral network 222 is adjusted repeatedly until the output data 223 is as the sensitive instances. After the training stage, the machine learning model 220 with the adjusted weight parameters can select the sensitive instances 230 from the circuit design 210.

In some embodiments, the instances are the electronic elements of the circuit design 210. For example, the circuit design 210 is implemented by the semiconductor device 200A shown in FIG. 2A. In such example, the instances of the circuit design 210 are the switches TP1-TP4 and TN1-TN3, and the sensitive instances 230 are the switches TP1 and TN3. Alternatively stated, when the parameters of the switches TP1 and TN3 are changed, the performance of the semiconductor device 200A has a larger variation, compared to a condition that the parameters of the switches TP2-TP4 and TN1-TN2 are changed.

Referring to FIG. 2B and FIG. 1, the schematic data 101 includes the circuit design 210. After the sensitive instances 230 are selected, the method 100 is performed to choose the parameter combination with the best performance of the circuit design 210. In some embodiments, after the parameter combination is chosen, the sensitive instances 230 are manufactured according to the parameter combination, such that the semiconductor device of the circuit design 210 has the best performance.

In various embodiments, the performance has various definitions. In semiconductor design, the performance corresponds to performance, power and area (PPA). The performance generally encompasses speed, throughput, latency, instruction execution efficiency, benchmarking and real-world performance of the semiconductor device of the circuit design 210.

In some embodiments, the performance of the circuit design 210 is associated with speed and frequency of the circuit design 210. The performance is often measured by the maximum operating frequency of the semiconductor device of the circuit design 210. The speed refers to how fast the semiconductor device can perform its operations, typically measured in hertz (Hz). Higher speed or frequency indicates that the semiconductor device can execute more instructions per second, which is critical for applications requiring rapid data processing. When the speed or frequency is higher, the performance of the circuit design 210 is higher.

In some embodiments, the performance of the circuit design 210 is associated with the throughput of the circuit design 210. The throughput is the amount of data processed by the semiconductor device of the circuit design 210 in a given time period, often measured in operations per second or bytes per second. High throughput is crucial for systems that need to handle large volumes of data efficiently, such as data centers or high-performance computing environments. When the throughput is higher, the performance of the circuit design 210 is higher.

In some embodiments, the performance of the circuit design 210 is associated with the latency of the circuit design 210. The latency refers to the time it takes for a specific operation to be completed once it has been initiated by the semiconductor device of the circuit design 210. Lower latency means faster response times, which is essential for real-time applications, such as gaming or autonomous vehicle systems. When the latency is higher, the performance of the circuit design 210 is lower.

In some embodiments, the performance of the circuit design 210 is associated with the instruction execution efficiency of the circuit design 210. The instruction execution efficiency involves the number of instructions the semiconductor device of the circuit design 210 can execute in a given cycle and how efficiently it executes complex instruction sets. Efficient instruction execution can lead to better overall performance, as it reduces the number of cycles required to complete tasks. When the instruction execution efficiency is higher, the performance of the circuit design 210 is higher.

In some embodiments, the performance of the circuit design 210 is associated with the benchmarking and real-world performance of the circuit design 210. The performance is often evaluated using standardized benchmarks that simulate real-world tasks to gauge how the semiconductor device of the circuit design 210 performs in practical applications. Benchmark scores provide a comparative measure against other designs or products, helping designers optimize for better real-world performance.

In summary, the performance in semiconductor design refers to how effectively a device can execute tasks, characterized by its speed, throughput, latency, and efficiency in executing instructions. Improving performance is a key objective in semiconductor design to meet the demands of various applications.

FIG. 3A is a schematic diagram of the operation OP11 shown in FIG. 1, for generating the parameter table 310, illustrated in accordance with some embodiments of the present disclosure. In some embodiments, during the operation OP11, the parameter table 310 of the sensitive instances 230 is auto-created. For example, as shown in FIG. 3A, the parameter table 310 of the switch TP1 is auto-created based on the range data 110 shown in FIG. 1.

As illustratively shown in FIG. 3A, the parameters l, simM, Fingers, srcCell, sim_flag, Analog_Cell_Type and the ranges of the parameters are listed in the parameter table 310. Further details regarding the automatic generation of the parameter table 310 are described below with the embodiments associated with FIG. 3B.

In some embodiments, the parameter l corresponds to a device length of the circuit design 210. The parameter simM corresponds to a number of parallel MOS devices in the circuit design 210. The parameter Fingers corresponds to a number of poly fingers in the circuit design 210. The parameter srcCell corresponds to a type of the switch TP1. For example, the parameter srcCell indicates that the switch TP1 is a PMOS transistor or a NMOS transistor, and operates under a standard thermal voltage or a low thermal voltage. The parameter Analog_Cell_Type corresponds to analog cell type of the circuit design 210. For example, the parameter Analog_Cell_Type indicates different cell height of the circuit design 210.

FIG. 3B is a schematic diagram of the operation OP11 shown in FIG. 1, regarding details of generating the parameter table 310, illustrated in accordance with some embodiments of the present disclosure.

As illustratively shown in FIG. 3B, an instance parameter table IPT1 and a parameter order table POT1 are generated according to the switch TP1, for generating the parameter table 310. Regarding the parameter order table POT1, a process used for manufacturing the circuit design 210 is determined, and a parameter order of the process is selected from the parameter order table POT1. For example, in response to the circuit design 210 manufactured by an N3 (3 nm semiconductor node) process of analog cell device, the parameter order 150 of the N3 process is selected from the parameter order table POT1. In the embodiment shown in FIG. 3B, the parameter order table POT1 includes parameter orders corresponding to an N2 (2 nm semiconductor node) process, the N3 process and an N4 (4 nm semiconductor node) process, respectively.

Regarding the instance parameter table IPT1, parameters are listed in the instance parameter table IPT1 based on the type of the instance 230. In various embodiments, the instance 230 has various types, such as a resistor type, a capacitor type or a transistor type.

In the embodiment shown in FIG. 3B, in response to the switch TP1 of the instance 230 being a PMOS transistor, the parameters l, simM, Fingers, srcCell, sim_flag and Analog_Cell_Type are listed in the instance parameter table IPT1. Furthermore, design values of the parameters are also listed in the instance parameter table IPT1. The design values in the instance parameter table IPT1 corresponds to the original design of the circuit design 210. The method 100 is performed to select a combination of design values with a higher performance for the circuit design 210.

In the embodiment shown by the instance parameter table IPT1, the design values of the parameters l, simM, Fingers, srcCell, sim_flag and Analog_Cell_Type are 55n, 1, 3, pch_svt_mac, OFF and HD_H130_MOS_R1, respectively.

Then, the ranges of the parameters shown in the instance parameter table IPT1 are listed in the parameter table 310. The ranges extend from the design values shown in the instance parameter table IPT1. Alternatively stated, the ranges include the design values and surround the design values.

Specifically, in response to the design value 55n of the parameter l, the range of parameter l is 3n, 55n and 86 n, which correspond to 3 nm, 55 nm and 86 nm, respectively. In response to the design value 1 of the parameter simM, the range of parameter simM is 1, 2 and 3. In response to the design value 3 of the parameter Fingers, the range of parameter Fingers is 1, 2, 3, 4 and 5. In response to the design value pch_svt_mac of the parameter srcCell, the range of parameter srcCell is pch_svt_mac, pch_lvt_mac, pch_ulvt_mac, pch_elvt_mac, pch_lvtll_mac and pch_ulvtll_mac. It is noted that the terms svt and lvt correspond to the standard thermal voltage and the low thermal voltage, respectively. In response to the design value HD_H130_MOS_R1 of the parameter Analog_Cell_Type, the range of parameter Analog_Cell_Type is HD_H130_MOS_R1, HD_H208_MOS_R1 and HD_H260_MOS_R1. It is noted that the values HD_H130_MOS_R1, HD_H208_MOS_R1 and HD_H260_MOS_R1 correspond to three different cell heights, respectively.

In some embodiments, the parameters in the instance parameter table IPT1 are compared with the parameters in the parameter order 150. One or more parameter in the instance parameter table IPT1 is removed from the parameter table 310 when the one or more parameter is not listed in the parameter order 150. For example, in response to the parameter sim_flag being not listed in the parameter order 150 of the N3 process, the parameter sim_flag is removed from the parameter table 310.

FIG. 3C is a schematic diagram of the operation OP12 shown in FIG. 1, for generating an user modified parameter table 310C, illustrated in accordance with some embodiments of the present disclosure.

As illustratively shown in FIG. 3C, during the operation OP12, user-defined values and user-defined parameters are added to the parameter table 310, to generate the user modified parameter table 310C. For example, a user-defined value 90n is added into the range of the parameter l. A user-defined value 4 is added into the range of the parameter simM. User-defined parameters lg and abc are added in user modified parameter table 310C.

FIG. 3D is a schematic diagram of the operation OP13 shown in FIG. 1, for sorting a sequence of the parameters according to the parameter order 150, illustrated in accordance with some embodiments of the present disclosure. As illustratively shown in FIG. 3D, during the operation OP13, the sorted parameter table 310D is generated according to the parameter order 150 and the user modified parameter table 310C. Specifically, the parameters in the user modified parameter table 310C are arranged according to the sequence of the parameter order 150, to generate the sorted parameter table 310D.

In some embodiment, the operation OP12 is not performed. In such embodiment, the user modified parameter table 310C is replaced by the parameter table 310 in the description above. Alternatively stated, the parameters in the parameter table 310 are arranged according to the sequence of the parameter order 150, to generate the sorted parameter table 310D.

In the embodiment shown in FIG. 3D, the parameter order 150 corresponds to the N3 process. During the operation OP13, the parameters Analog_Cell_Type, srcCell, l, nfin, Fingers, decomCnt, m and simM are arranged in sequence in the parameter order 150. The sequence corresponds to priorities of the parameters for a simulation tool, such as a simulation tool 715 shown in FIG. 7.

For example, according to the parameter order 150, the parameter Analog_Cell_Type has priority over the parameter srcCell. The parameter srcCell has priority over the parameter l. The parameter l has priority over the parameter Fingers. The parameter srcCell has priority over the parameter simM. Correspondingly, the parameters in the sorted parameter table 310D are arranged to be conformed to the priorities.

On the other hand, during the operation OP13, invalid parameters and invalid parameter values are removed from the sorted parameter table 310D. For example, in response to the value 90n being an invalid parameter value of the parameter l, the value 90n is removed from the sorted parameter table 310D. In response to the parameters lg and abc being invalid parameters, the parameters lg and abc are removed from the sorted parameter table 310D. In some embodiments, the invalid parameters are non-editable parameters or non-existed parameter for the simulation tool 715, and the invalid parameter values are not available for the simulation tool 715.

FIG. 3E is a schematic diagram of the operation OP14 shown in FIG. 1, for removing the invalid combinations according to predetermined rules, illustrated in accordance with some embodiments of the present disclosure. In some embodiments, the predetermined rules are created based on the feasibility of the manufacturing process (such as the N3 process) of the circuit design 210 and compliance of the circuit design 210 with design rules, among other aspects. In some embodiments, the predetermined rules are stored in a storage medium, such as computer readable storage medium 704 shown in FIG. 7.

As illustratively shown in FIG. 3E, during the operation OP14, the combinations of the parameters in the sorted parameter table 310D are checked, and the invalid combinations are removed, to generate the valid combination table 310E.

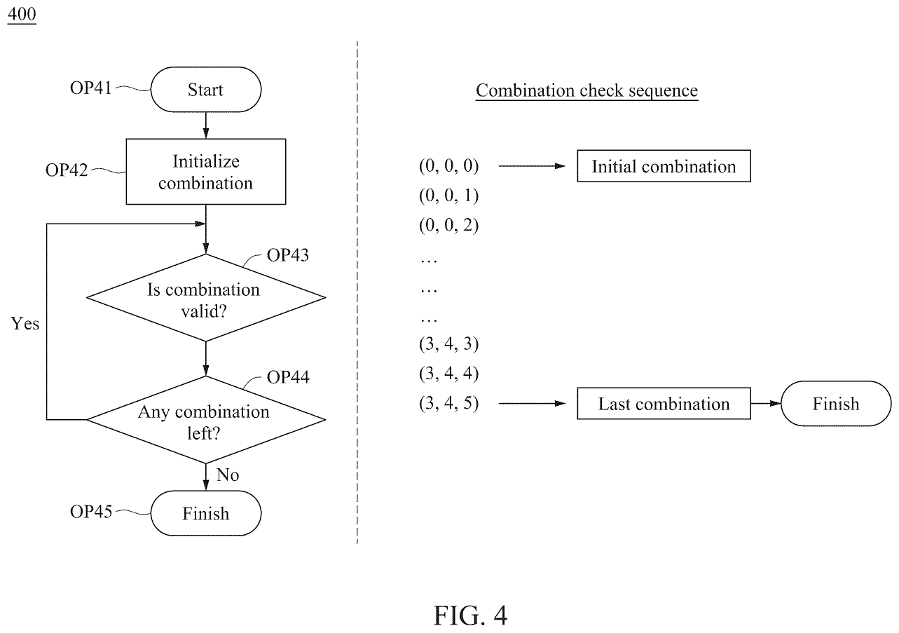

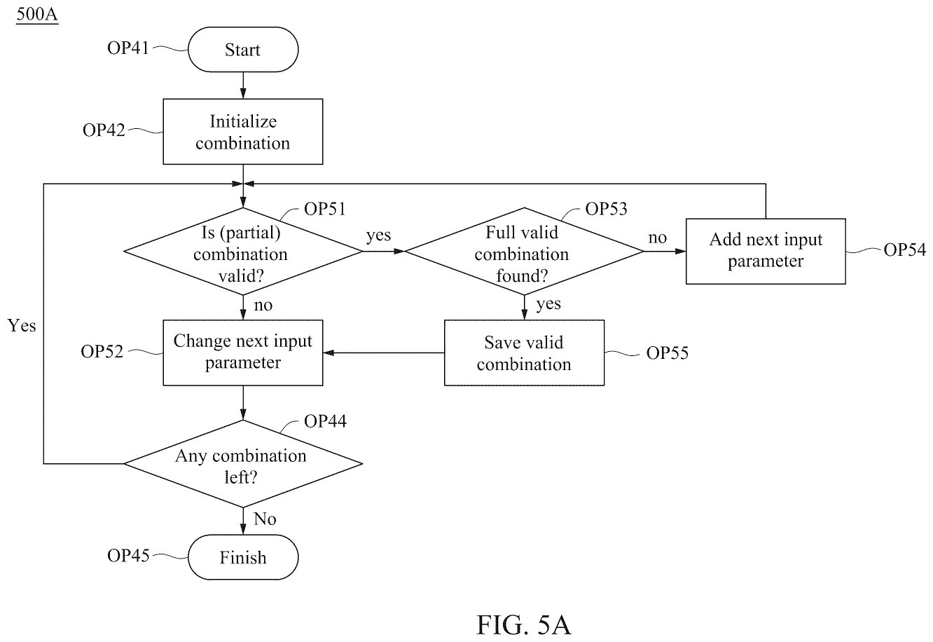

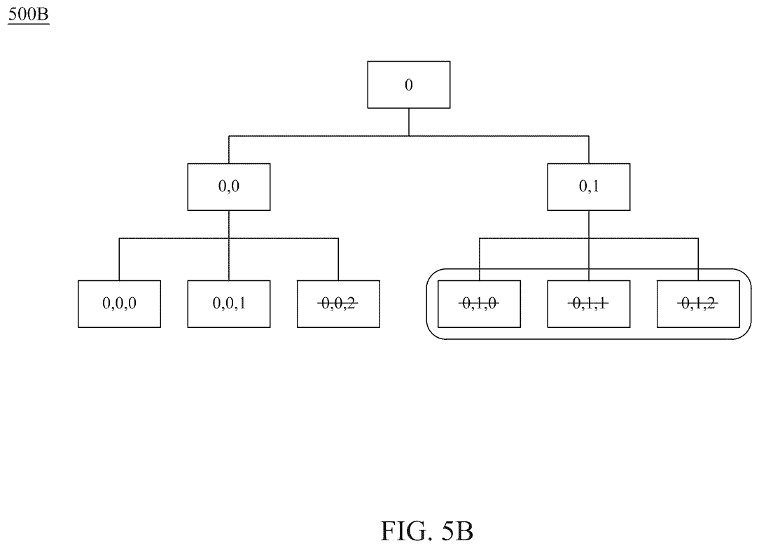

Specifically, each of the combinations is evaluated with the predetermined rules. In response to a combination being conformed to the predetermined rules, the combination is inputted into the valid combination table 310E. In response to a combination being not conformed to the predetermined rules, the combination is rejected and not inputted into the valid combination table 310E. After all combinations of the sorted parameter table 310D are checked, the entire valid combination table 310E is generated. Accordingly, the combinations in the valid combination table 310E are the valid combinations. Further details of the operation OP14 are described below with the embodiments associated with FIG. 4, FIG. 5A and FIG. 5B.

After the operation OP14, the simulation tool 715 executes simulations of the combinations in the valid combination table 310E, to obtain the performances of the valid combinations.

In some approaches, a simulation tool executes simulations to all parameter combinations. However, some of these combinations are invalid. The simulation tool still runs the simulation by wrong parameter values and lead to wrong results. As a result, some simulation runtime is wasted. Furthermore, the combinations with incorrect setting sequence lead to unexpected optimization results.

Compared to above approaches, in some embodiments of present disclosure, by performing the operation OP14, the invalid combinations are removed. The simulation tool 715 executes the simulations of the valid combinations shown in the valid combination table 310E. As a result, the simulation time is reduced effectively. On the other hand, by performing the operation OP13, the parameters are sorted according to the parameter order 150. As a result, the correctness of setting order of the parameters is ensured based on the priorities of the parameters.

FIG. 4 is a flowchart diagram of a method 400 for performing the operation OP14 shown in FIG. 3E, illustrated in accordance with some embodiments of the present disclosure. In some embodiments, the method 400 is referred to as a method of brute force algorithm. As illustratively shown in FIG. 4, the method 400 includes operations OP41-OP45.

During the operation OP41, the method 400 is started.

During the operation OP42, the combination of the parameters is initialized to the initial combination (0, 0, 0). In the embodiment shown in FIG. 3E, the initial combination (0, 0, 0) is the combination that the parameters Analog_Cell_Type, srcCell, l, Fingers and simM have the values HD_H130_MOS_R1, pch_svt_mac, 3n, 1 and 1, respectively.

During the operation OP43, the combination is checked being valid or invalid. Specifically, the combination is evaluated by the predetermined rules. When the combination is conformed to the predetermined rules, the combination is valid. When the combination is not conformed to the predetermined rules, the combination is invalid.

During the operation OP44, the combinations being not determined by the operation OP43 are evaluated. When there are combinations left to be not determined by the operation OP43, the operation OP43 is performed again to one of the left combinations. When there are no combinations left, the operation OP45 is performed.

In some embodiments, the operation OP43 is performed according to a combination check sequence. After the combination (0, 0, 0) is checked, the parameter with the lowest priority is changed to generate a combination (0, 0, 1) to be check by the operation OP43. In the embodiment shown in FIG. 4, the first parameter, the second parameter and the third parameter has the first priority, the second priority and the third priority, respectively. After combinations (0, 0, 0)-(0, 0, 5) are checked in sequence, the combinations (0, 1, 0)-(0, 1, 5) are checked in sequence. After combinations (0, 1, 0)-(0, 1, 5) are checked in sequence, combinations (0, 2, 0)-(0, 2, 5) are checked in sequence, and so on. After combinations (3, 3, 0)-(3, 3, 5) are checked in sequence, combinations (3, 4, 0)-(3, 4, 5) are checked in sequence. In response to the combination (3, 4, 5) being the last combination, after the combination (3, 4, 5) is checked by the operation OP43, the operation OP44 is performed to determine that no combination is left, and the operation OP45 is performed.

During the operation OP45, the method 400 is finished.

Referring to FIG. 3E and FIG. 4, the combination (0, 0, 1) is the combination that the parameters Analog_Cell_Type, srcCell, l, Fingers and simM have the values HD_H130_MOS_R1, pch_svt_mac, 3n, 1 and 2, respectively. In response to the combination (0, 0, 0) being valid, the combination (0, 0, 0) is inputted into the valid combination table 310E. In response to the combination (0, 0, 1) being invalid, the combination (0, 0, 1) is removed and is not inputted into the valid combination table 310E. After the method 400 is finished, the entire valid combination table 310E is generated.

FIG. 5A is a flowchart diagram of another method 500A for performing the operation OP14 shown in FIG. 3E, illustrated in accordance with some embodiments of the present disclosure. In some embodiments, the method 500A is referred to as a method of backtracking algorithm with combination filter. Referring to FIG. 4 and FIG. 5A, the method 500A is an alternative embodiment of the method 400. FIG. 5A follows a similar labeling convention to that of FIG. 4. For brevity, the discussion will focus more on differences between FIG. 5A and FIG. 4 than on similarities.

Compared to the method 400, the method 500A includes operations OP51-OP55 instead of the operation OP43. The operations OP51-OP55 are performed after the operation OP42.

FIG. 5B is a schematic diagram 500B of for performing the method 500A shown in FIG. 5A, illustrated in accordance with some embodiments of the present disclosure. Partial combinations (0), (0, 0), (0, 1) and the combinations (0, 0, 0)-(0, 0, 2), (0, 1, 0)-(0, 1, 2).

Referring to FIG. 5A and FIG. 5B, during the operation OP51, the combination or the partial combination is checked being valid or invalid. Specifically, the combination or the partial combination is evaluated by the predetermined rules. When the combination or the partial combination is conformed to the predetermined rules, the combination or the partial combination is valid. When the combination or the partial combination is not conformed to the predetermined rules, the combination or the partial combination is invalid.

When the combination or the partial combination is valid, the operation OP53 is performed after the operation OP51. When the combination or the partial combination is invalid, the operation OP52 is performed after the operation OP51.

During the operation OP52, a parameter in the invalid combination or the invalid partial combination is changed. For example, when the partial combination (0, 1) is invalid, a second parameter is changed from 1 to 2, to generate a partial combination (0, 2). The operation OP44 is performed after the operation OP52.

During the operation OP53, the valid combination is identified as being a full combination or a partial combination, to determine whether a full valid combination is found. When the valid combination is a partial combination, the operation OP54 is performed after the operation OP53. When the valid combination is a full combination, the operation OP55 is performed after the operation OP53. In the embodiment shown in FIG. 5B, the combinations (0), (0, 0), (0, 1) are partial combinations, and the combinations (0, 0, 0)-(0, 0, 2), (0, 1, 0)-(0, 1, 2) are full combinations.

During the operation OP54, a parameter is added into the combination. For example, after the operation OP53 is performed to the valid partial combination (0), a second parameter is added to the valid partial combination (0), to generate the partial combination (0, 0). For another example, after the operation OP53 is performed to the valid partial combination (0, 0), a third parameter is added to the valid partial combination (0, 0), to generate the combination (0, 0, 0). The operation OP51 is performed after the operation OP44.

During the operation OP55, the valid combination is saved into a valid combination table, such as the valid combination table 310E shown in FIG. 3E. The operation OP52 is performed after the operation OP55.

During the operation OP44, the combinations being not determined by the operation OP51 are evaluated. When there are combinations left to be not determined by the operation OP51, the operation OP51 is performed again to one of the left combinations. When there are no combinations left, the operation OP45 is performed.

Details of the embodiment shown FIG. 5B are described below. During the operation OP51, the combination (0) is checked being valid. Then, the operation OP53 is performed to the combination (0) to identify that the combination (0) is a partial combination. Then, the second parameter is added into the combination (0) to generate the combination (0, 0) by the operation OP54.

Then, the operation OP51 is performed to the combination (0, 0) to check that the combination (0, 0) is valid. Then, the operation OP53 is performed to the combination (0, 0) to identify that the combination (0, 0) is a partial combination. Then, the third parameter is added into the combination (0, 0) to generate the combination (0, 0, 0) by the operation OP54.

Then, the operation OP51 is performed to the combination (0, 0, 0) to check that the combination (0, 0, 0) is valid. Then, the operation OP53 is performed to the combination (0, 0, 0) to identify that the combination (0, 0, 0) is a full combination. Then, the operation OP52 is performed to combination (0, 0, 0), to generate the combination (0, 0, 1).

Then, the operation OP51 is performed to the combination (0, 0, 1) to check that the combination (0, 0, 1) is valid. Then, the operation OP53 is performed to the combination (0, 0, 1) to identify that the combination (0, 0, 1) is a full combination. Then, the operation OP55 is performed to the combination (0, 0, 1), to save the combination (0, 0, 1). Then, the operation OP52 is performed to the combination (0, 0, 1), to generate the combination (0, 0, 2). Then, the operation OP44 is performed to determine that the combination (0, 0, 2) is not checked to be valid or invalid.

Then, the operation OP51 is performed to the combination (0, 0, 2) to check that the combination (0, 0, 2) is invalid. Then, the operation OP52 is performed to combination (0, 0, 2). However, the range of the third parameter is 0, 1 and 2. Alternatively stated, the combinations with the partial combination (0, 0) are checked by the operation OP51. Accordingly, a combination without the partial combination (0, 0) is searched for performing the operation OP51.

Then, the operation OP51 is performed to the combination (0, 1) to check that the combination (0, 1) is invalid. Accordingly, the combinations (0, 1, 0), (0, 1, 1) and (0, 1, 2), which include the combination (0, 1), are invalid. Therefore, the combinations (0, 1, 0), (0, 1, 1) and (0, 1, 2) do not need to be check by the predetermined rules. Then, the operation OP52 is performed to the combination (0, 1), to generate the combination (0, 2). Then, the operation OP51 is performed to the combination (0, 2) to check the combination (0, 2), and so on. By performing the method 500A, the time of operation OP14 is saved by skipping the combinations with the invalid partial combinations.

Referring to FIG. 5B and FIG. 3E, the partial combination (0) can be implemented by a partial combination that the parameter Analog_Cell_Type has the value HD_H130_MOS_R1. The partial combination (0, 0) can be implemented by a partial combination that the parameters Analog_Cell_Type and srcCell have the values HD_H130_MOS_R1 and pch_svt_mac, respectively. The partial combination (0, 1) can be implemented by a partial combination that the parameters Analog_Cell_Type and srcCell have the values HD_H130_MOS_R1 and pch_lvt_mac, respectively.

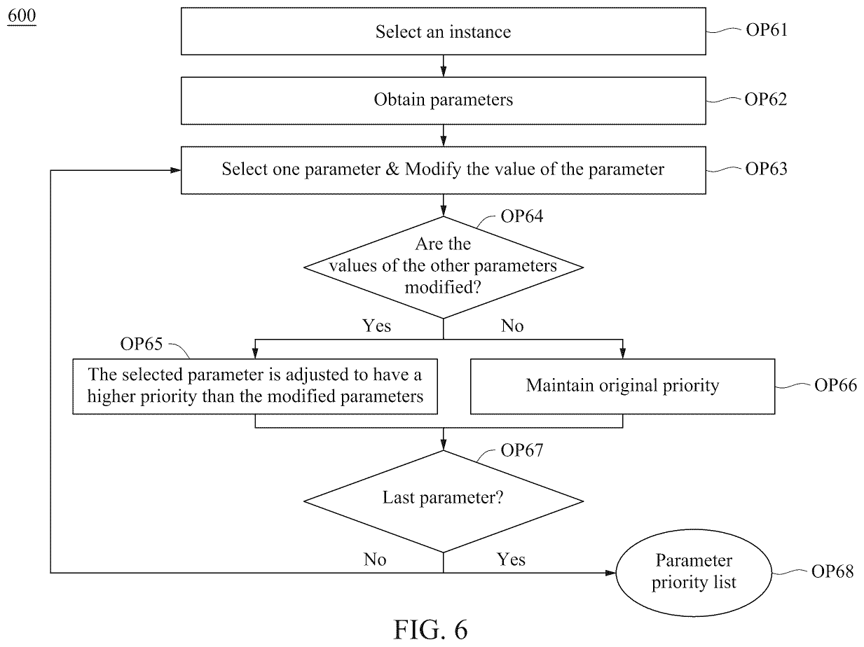

FIG. 6 is a flowchart diagram of a method 600 for generating a parameter priority list, illustrated in accordance with some embodiments of the present disclosure. As illustratively shown in FIG. 6, the method 600 includes operations OP61-OP68.

During the operation OP61, an instance is selected. For example, the switch TP1 shown in FIG. 3A is selected as the instance.

During the operation OP62, parameters associated with the instance are obtained. For example, parameters associated with the switch TP1 are obtained.

During the operation OP63, one parameter is selected from the parameters, and a value of the one parameter is modified. For example, the parameter srcCell of the parameters associated with the switch TP1 is chosen, and the parameter srcCell is modified from the value pch_svt_mac to the value pch_lvt_mac.

In some embodiments, for the simulation tool 715, when the value of the selected parameter is modified, values of other parameters with lower priorities than the selected parameter are automatically modified, and values of other parameters with higher priorities than the selected parameter are maintained.

Accordingly, during the operation OP64, the processor checks whether the values of the other parameters are modified. In response to at least one of the other parameters modified, the operation OP65 is performed after the operation OP64. In response to each of the other parameters is maintained, the operation OP66 is performed after the operation OP64.

During the operation OP65, the priority of the selected parameter is adjusted, such that the selected parameter has a higher priority than the modified parameters.

During the operation OP66, the priority of the selected parameter is maintained as the original priority.

During the operation OP67, the processor checks whether the selected parameter is the last parameter being selected. In response to the selected parameter being the last parameter, the operation OP68 is performed. In response to the selected parameter being not the last parameter, the operation OP63 is performed again to select another parameter, and the operation OP64 are performed again to the other selected parameter.

During the operation OP68, the parameter priority list is generated. Referring to FIG. 6 and FIG. 3D, the parameter priority list can be implemented by the parameter order 150.

An example is described below with the parameters shown in the sorted parameter table 310D. In this example, the original priority is arranged as Analog_Cell_Type, l, srcCell, Fingers and simM. The operation OP64 is performed to modify the value of the parameter Analog_Cell_Type. Since the priority of the parameter Analog_Cell_Type is higher than each of the priorities of the parameters l, srcCell, Fingers and simM, the priority of the parameter Analog_Cell_Type is maintained. Then, since the parameter Analog_Cell_Type is not the last parameter being selected, the parameter l is selected.

Then, since the priority of the parameter l is higher than each of the priorities of the parameters Fingers and simM, the priority of the parameter l is maintained. Then, since the parameter l is not the last parameter being selected, the parameter srcCell is selected. When the value of the parameter srcCell is modified, the value of the parameter l is modified. Correspondingly, the operation OP65 is performed to adjust the priority of the parameter srcCell to be higher than the parameter l, and so on. Eventually, when the operation OP67 is performed to the parameter simM, in response to the parameter simM is the last selected parameter, the operation OP68 is performed.

FIG. 7 is a schematic view of a system 700 for performing at least one of the method and operations described above, illustrated in accordance with some embodiments of the present disclosure. The system 700 generates or places one or more IC layout designs corresponding to the semiconductor devices as described herein. In some embodiments, the system 700 manufactures one or more semiconductor devices based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 performing at least one of the method and operations described above.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for performing at least one of the method and operations described above, such as layout design 716, user interface 717, fabrication unit 720, and/or a set of executable instructions to perform at least one of the method and operations described above.

In some embodiments, the storage medium 704 also stores the simulation tool 715. The simulation tool 715 is configured to execute the simulation of the valid combinations of the parameters described above, to generate the corresponding performances.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor devices designed by the method described above.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, at least one of the method and operations described above is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 717. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, the performing at least one of the method and operations described above is implemented as a standalone software application for execution by a processor. In some embodiments, the performing at least one of the method and operations described above is implemented as a software application that is a part of an additional software application. In some embodiments, the performing at least one of the method and operations described above is implemented as a plug-in to a software application. In some embodiments, the performing at least one of the method and operations described above is implemented as a software application that is a portion of an EDA tool. In some embodiments, the performing at least one of the method and operations described above is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the semiconductor devices designed by the method described above is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

In some embodiments, the computer readable storage medium 704 is configured to store a circuit design 210, a parameter order table POT1, a instance parameter table IPT1 of an instance, such as the switch TP1, in the circuit design 210 and a simulation tool 715.

In some embodiments, the processor 702 is configured to select the parameter order 150 from the parameter order table POT1 based on the instance. For example, the parameter order 150 is selected based on the switch TP1 corresponding to the N3 process. The processor 702 is further configured to compare the parameter order 150 with the instance parameter table IPT1 to generate the parameter table 310.

In some embodiments, the processor 702 is further configured to sort a first parameter group in the parameter table 310 based on the parameter order 150. For example, the processor 702 sort the first parameter group which includes parameters l, simM, Fingers, srcCell, and Analog_Cell_Type based on the parameter order 150.

In some embodiments, the processor 702 is further configured to check the combinations of the first parameter group and remove the invalid combinations, to generate the valid combinations. For example, the processor 702 checks the combinations of the first parameter group in the sorted parameter table 310D with the predetermined rules, and removes the invalid combinations from the combinations, to generate the valid combinations in the valid combination table 310E.

In some embodiments, the processor 702 is further configured to execute the simulation tool 715 to generate performances of the valid combinations in the valid combination table 310E, and compare the performances to select a first valid combination from the valid combinations, in which the first valid combination has the best performance among the valid combinations.

For example, in response to the combination that the parameters Analog_Cell_Type, srcCell, l, Fingers and simM respectively have the values HD_H130_MOS_R1, pch_svt_mac, 3n, 1 and 1 having a highest speed among the combinations in the valid combination table 310E, this combination is selected to be the first valid combination. Then, the fabrication tool 722 is configured to manufacture a semiconductor device based on the circuit design 210 and the first valid combination.

In some embodiments, the processor 702 is further configured to check a first partial combination of the first parameter group. When the first partial combination is valid, the processor 702 is further configured to add a parameter in the first parameter group to the first partial combination to generate a first combination, and check the first combination.

For example, the processor 702 checks the partial combination (0, 0) or (0, 1) of the first parameter group. When the partial combination (0, 0) is valid, the processor 702 adds a third parameter in the first parameter group to the partial combination (0, 0) to generate the combination (0, 0, 0), and checks the combination (0, 0, 0).

In some embodiments, when the first partial combination is invalid, the processor 702 is further configured to remove at least one invalid combination. Each of the at least one invalid combination comprises the first partial combination. For example, when the partial combination (0, 1) is invalid, the processor 702 removes the invalid combination (0, 1, 0)-(0, 1, 2). Each of the invalid combination (0, 1, 0)-(0, 1, 2) comprises the partial combination (0, 1).

In some embodiments, when the first partial combination is invalid, the processor 702 is further configured to change a parameter in the first partial combination to generate a second partial combination, and check the second partial combination. For example, when the partial combination (0, 1) is invalid, the processor 702 changes the second parameter in the partial combination (0, 1) to generate the partial combination (0, 2), and checks the partial combination (0, 2).

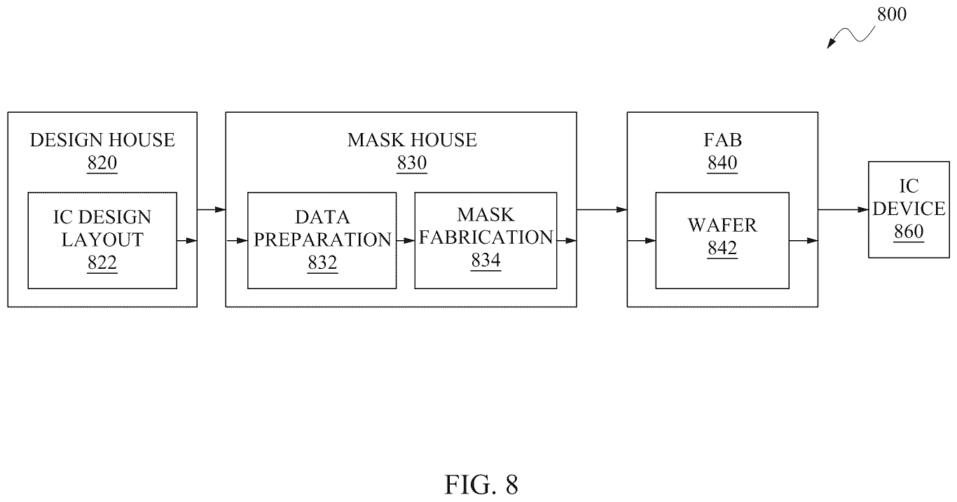

FIG. 8 is a block diagram of an integrated circuit (IC)/semiconductor device manufacturing system 800, and an IC manufacturing flow associated therewith, illustrated in accordance with some embodiments of the present disclosure.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including the semiconductor devices designed by the method described above. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the above description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

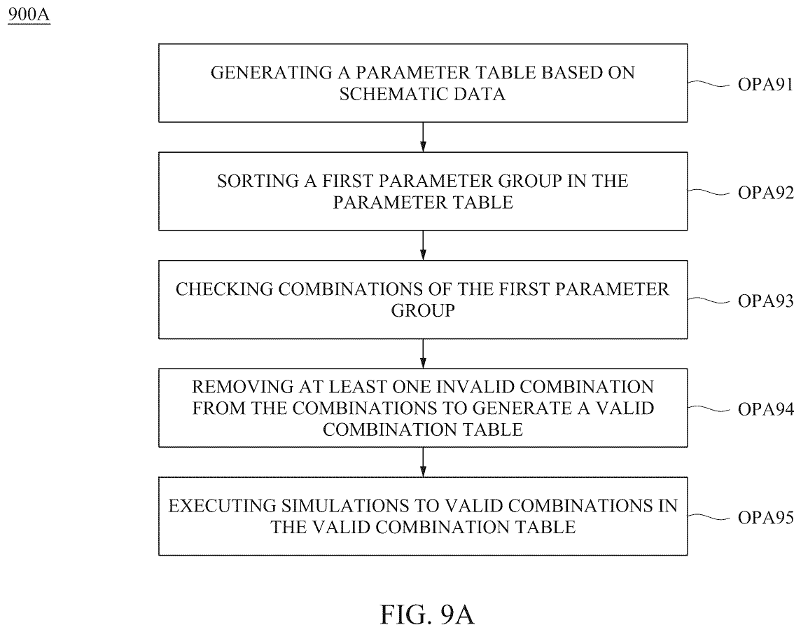

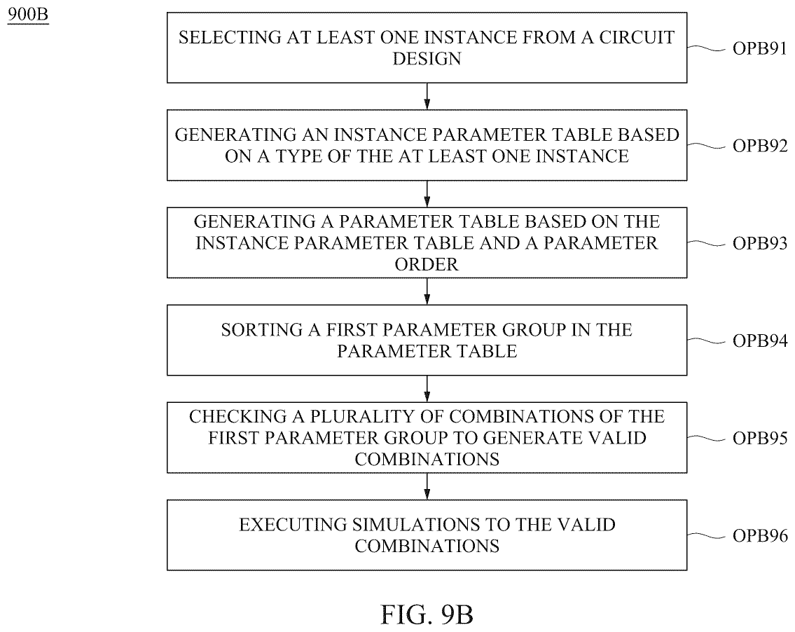

FIG. 9A is a flowchart diagram of a method 900A for designing the semiconductor device of the circuit design 210, illustrated in accordance with some embodiments of the present disclosure. The method 900A includes operations OPA91-OPA95.

During the operation OPA91, the processor 702 generates the parameter table 310 based on the schematic data 101.

During the operation OPA92, the processor 702 sorts the first parameter group in the parameter table 310.

During the operation OPA93, the processor 702 checks combinations of the first parameter group.

During the operation OPA94, the processor 702 removes at least one invalid combination from the combinations to generate the valid combination table 310E.

During the operation OPA94, the processor 702 executes simulations to valid combinations in the valid combination table 310E.

In some embodiments, the processor 702 selects the instance 230 from the circuit design 210 of the schematic data 101, and generates the instance parameter table IPT1 based on the type of the instance 230. The processor 702 selects the parameter order 150 from the parameter order table POT1 according to a manufacturing process, such as the N3 process of the circuit design 210. The processor 702 compares a second parameter group in the parameter order 150 and a third parameter group in the instance parameter table IPT1 to determine the first parameter group.

In some embodiments, when each of the second parameter group and the third parameter group includes the parameter srcCell, the processor 702 inputs the parameter srcCell into the parameter table 310. When the second parameter group does not include the parameter sim_flag included in the third parameter group, removing the parameter sim_flag from the parameter table 310.

In some embodiments, the processor 702 sorts the first parameter group based on the parameter order 150 to generate the sorted parameter table 310D, and checks combinations based on the sorted parameter table 310D.

In some embodiments, the processor 702 checks the partial combination (0, 0) or (0, 1) of the first parameter group. When the partial combination (0, 0) is valid, the processor 702 adds a third parameter in the first parameter group to the partial combination (0, 0) to generate the combination (0, 0, 0), and checks the combination (0, 0, 0).

In some embodiments, when the partial combination (0, 1) is invalid, the processor 702 removes the invalid combinations (0, 1, 0)-(0, 1, 2). Each of the invalid combinations (0, 1, 0)-(0, 1, 2) comprises the partial combination (0, 1).

In some embodiments, when the partial combination (0, 1) is invalid, the processor 702 changes the second parameter in the partial combination (0, 1) to generate the partial combination (0, 2), and checks the partial combination (0, 2).

In some embodiments, the processor 702 evaluates each of the combinations with the predetermined rules. When a first combination of the combinations being conformed to the predetermined rules, the processor 702 inputs the first combination into the valid combination table 310E. When a second combination of the combinations being not conformed to the predetermined rules, the processor 702 removes the second combination.

FIG. 9B is a flowchart diagram of a method 900B for designing the semiconductor device of the circuit design 210, illustrated in accordance with some embodiments of the present disclosure. The method 900B includes operations OPB91-OPA96.

During the operation OPB91, the processor 702 selects the instance 230 from the circuit design 210.

During the operation OPB92, the processor 702 generates the instance parameter table IPT1 based on the type of the instance 230.

During the operation OPB93, the processor 702 generates the parameter table 310 based on the instance parameter table IPT1.

During the operation OPB94, the processor 702 sorts the first parameter group in the parameter table 310.

During the operation OPB95, the processor 702 checks the combinations of the first parameter group to generate the valid combinations, such as the valid combinations shown in the valid combination table 310E.

During the operation OPB96, the processor 702 executes simulations to the valid combinations.

In some embodiments, the processor 702 selects a parameter order 150 from the parameter order table POT1 according to a manufacturing process (such as the N3 process) of the circuit design 210. The processor 702 compares a second parameter group in the parameter order 150 and a third parameter group in the instance parameter table IPT1 to determine the first parameter group.

In the embodiment shown in FIG. 3B, the first parameter group includes the parameters l, simM, Fingers, srcCell and Analog_Cell_Type. The second parameter group includes the parameters l, simM, Fingers, srcCell, sim_flag and Analog_Cell_Type. The third parameter group includes the parameters Analog_Cell_Type, srcCell, l, nfin, Fingers, decomCnt, m and simM.

In some embodiments, when each of the second parameter group and the third parameter group includes the parameter srcCell, the processor 702 inputs the parameter srcCell into the parameter table 310. When the second parameter group does not include the parameter sim_flag included in the third parameter group, the processor 702 removes the parameter sim_flag from the parameter table 310.

In some embodiments, the processor 702 sorts the first parameter group based on the parameter order 150 to generate the sorted parameter table 310D, and checks the combinations based on the sorted parameter table 310D.

In some embodiments, the processor 702 checks the partial combination (0, 0) or (0, 1) of the first parameter group. When the partial combination (0, 0) is valid, the processor 702 adds the third parameter in the first parameter group to the partial combination (0, 0) to generate the combination (0, 0, 0), and checks the combination (0, 0, 0).

In some embodiments, after the combination (0, 0, 0) is checked, the processor 702 changes the third parameter of the combination (0, 0, 0) with a lowest priority in the parameter order 150, to generate the combination (0, 0, 1), and checks the combination (0, 0, 1).

In some embodiments, when the partial combination (0, 1) is invalid, the processor 702 removes the invalid combination (0, 1, 0)-(0, 1, 2). Each of the invalid combination (0, 1, 0)-(0, 1, 2) includes the partial combination (0, 1).

In some embodiments, when the partial combination (0, 1) is invalid, the processor 702 changes the second parameter in the partial combination (0, 1) to generate the partial combination (0, 2), and checks the partial combination (0, 2).

Also disclosed is a method. The method includes: generating a parameter table based on schematic data; sorting a first parameter group in the parameter table; checking a plurality of combinations of the first parameter group; removing at least one invalid combination from the plurality of combinations to generate a valid combination table; and executing simulations to a plurality of valid combinations in the valid combination table.

Also disclosed is a method. The method includes: selecting at least one instance from a circuit design; generating an instance parameter table based on a type of the at least one instance; generating a parameter table based on the instance parameter table and a parameter order; sorting a first parameter group in the parameter table; checking a plurality of combinations of the first parameter group to generate a plurality of valid combinations; and executing simulations to the plurality of valid combinations.

Also disclosed is a system. The system includes a computer readable storage medium, a processor and a fabrication tool. The computer readable storage medium is configured to store a circuit design, a parameter order table, a instance parameter table of an instance in the circuit design and a simulation tool. The processor is configured to: select a parameter order from the parameter order table based on the instance, compare the parameter order with the instance parameter table to generate a parameter table, sort a first parameter group in the parameter table based on the parameter order, check a plurality of combinations of the first parameter group and remove a plurality of invalid combinations, to generate a plurality of valid combinations, execute the simulation tool to generate a plurality of performances of the plurality of valid combinations, and compare the plurality of performances to select a first valid combination from the plurality of valid combinations. The fabrication tool is configured to manufacture a semiconductor device based on the circuit design and the first valid combination.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
generating a parameter table based on schematic data;
sorting a first parameter group in the parameter table;
checking a plurality of combinations of the first parameter group;
removing at least one invalid combination from the plurality of combinations to generate a valid combination table; and
executing simulations to a plurality of valid combinations in the valid combination table.

2. The method of claim 1, wherein generating the parameter table comprises:
selecting at least one instance from a circuit design of the schematic data;
generating an instance parameter table based on a type of the at least one instance;
selecting a parameter order from a parameter order table according to a manufacturing process of the circuit design; and
comparing a second parameter group in the parameter order and a third parameter group in the instance parameter table to determine the first parameter group.

3. The method of claim 2, wherein generating the parameter table further comprises:
when each of the second parameter group and the third parameter group includes a first parameter, inputting the first parameter into the parameter table; and
when the second parameter group does not include a second parameter included in the third parameter group, removing the third parameter from the parameter table.

4. The method of claim 2, wherein sorting the first parameter group comprises sorting the first parameter group based on the parameter order to generate a sorted parameter table, and
checking the plurality of combinations comprises checking the plurality of combinations based on the sorted parameter table.

5. The method of claim 1, wherein checking the plurality of combinations comprises:
checking a first partial combination of the first parameter group;
when the first partial combination is valid, adding a parameter in the first parameter group to the first partial combination to generate a first combination; and
checking the first combination.

6. The method of claim 5, wherein removing the at least one invalid combination comprises:
when the first partial combination is invalid, removing at least one invalid combination,
wherein each of the at least one invalid combination comprises the first partial combination.

7. The method of claim 6, further comprising:
when the first partial combination is invalid, changing a parameter in the first partial combination to generate a second partial combination; and
checking the second partial combination.

8. The method of claim 1, wherein checking the plurality of combinations and removing the at least one invalid combination comprise:
evaluating each of the plurality of combinations with a plurality of predetermined rules;
when a first combination of the plurality of combinations being conformed to the predetermined rules, inputting the first combination into the valid combination table; and
when a second combination of the plurality of combinations being not conformed to the predetermined rules, removing the second combination.

9. A method, comprising:
selecting at least one instance from a circuit design;
generating an instance parameter table based on a type of the at least one instance;
generating a parameter table based on the instance parameter table and a parameter order;
sorting a first parameter group in the parameter table;
checking a plurality of combinations of the first parameter group to generate a plurality of valid combinations; and
executing simulations to the plurality of valid combinations.

10. The method of claim 9, wherein generating the parameter table comprises:
selecting the parameter order from a parameter order table according to a manufacturing process of the circuit design; and
comparing a second parameter group in the parameter order and a third parameter group in the instance parameter table to determine the first parameter group.

11. The method of claim 10, wherein generating the parameter table further comprises:
when each of the second parameter group and the third parameter group includes a first parameter, inputting the first parameter into the parameter table; and
when the second parameter group does not include a second parameter included in the third parameter group, removing the second parameter from the parameter table.

12. The method of claim 11, wherein sorting the first parameter group comprises sorting the first parameter group based on the parameter order to generate a sorted parameter table, and
checking the plurality of combinations comprises checking the plurality of combinations based on the sorted parameter table.

13. The method of claim 9, wherein checking the plurality of combinations comprises:
checking a first partial combination of the first parameter group;
when the first partial combination is valid, adding a parameter in the first parameter group to the first partial combination to generate a first combination; and
checking the first combination.

14. The method of claim 13, wherein checking the plurality of combinations further comprises:
after the first combination is checked, changing a parameter of the first combination with a lowest priority in the parameter order, to generate a second combination; and
checking the second combination.

15. The method of claim 13, further comprising:
when the first partial combination is invalid, removing at least one invalid combination,
wherein each of the at least one invalid combination comprises the first partial combination.

16. The method of claim 15, further comprising:
when the first partial combination is invalid, changing a parameter in the first partial combination to generate a second partial combination; and
checking the second partial combination.

17. A system, comprising:
a computer readable storage medium configured to store a circuit design, a parameter order table, a instance parameter table of an instance in the circuit design and a simulation tool;
a processor configured to:
select a parameter order from the parameter order table based on the instance,
compare the parameter order with the instance parameter table to generate a parameter table,
sort a first parameter group in the parameter table based on the parameter order,
check a plurality of combinations of the first parameter group and remove a plurality of invalid combinations, to generate a plurality of valid combinations,
execute the simulation tool to generate a plurality of performances of the plurality of valid combinations, and
compare the plurality of performances to select a first valid combination from the plurality of valid combinations; and
a fabrication tool configured to manufacture a semiconductor device based on the circuit design and the first valid combination.

18. The system of claim 17, wherein the processor is further configured to:
check a first partial combination of the first parameter group,
when the first partial combination is valid, add a parameter in the first parameter group to the first partial combination to generate a first combination, and
check the first combination.

19. The system of claim 18, wherein the processor is further configured to:
when the first partial combination is invalid, remove at least one invalid combination,
wherein each of the at least one invalid combination comprises the first partial combination.

20. The system of claim 19, wherein the processor is further configured to:
when the first partial combination is invalid, change a parameter in the first partial combination to generate a second partial combination, and
check the second partial combination.
